(19) United States
(12) Patent Application Publication
(10) Pub. No.: US 2025/0324856 A1
(43) Pub. Date: Oct. 16, 2025

(54) DISPLAY DEVICE AND ELECTRONIC DEVICE INCLUDING THE SAME

(71) Applicant: Samsung Display Co., Ltd., Yongin-si (KR)

(72) Inventors: WOO YONG SUNG, Yongin-si (KR); Hee Jun YANG, Yongin-si (KR); SEUNGYONG SONG, Yongin-si (KR)

(21) Appl. No.: 19/080,049

(22) Filed: Mar. 14, 2025

(30) Foreign Application Priority Data
Apr. 15, 2024 (KR) 10-2024-0050274

(51) Int. Cl. H10K 59/122; H10K 59/80

(52) U.S. Cl. CPC H10K 59/122; H10K 59/873

(57) ABSTRACT

An electronic device including a display panel which generates an image, the display panel including an insulating layer which defines a first groove therein, a light emitting element on the insulating layer, a pixel definition layer which is on the insulating layer and defines each of a light emitting opening which exposes the first electrode to outside the pixel definition layer, a first hole which is adjacent to the light emitting opening and overlaps the first groove, and a first tip portion which overlaps the first groove, and a layer which is on the light emitting element and contacts an upper surface, a side surface and a lower surface of the first tip portion.

This application claims priority to Korean Patent Application No. 10-2024-0050274, filed on Apr. 15, 2024, and all the benefits accruing therefrom under 35 U.S.C. § 119, the disclosure of which is incorporated by reference herein in its entirety.

### BACKGROUND

### 1. Field

The present disclosure relates to a display device. More particularly, the present disclosure relates to a display device with improved reliability related to moisture penetration and an electronic device including the same.

### 2. Description of Related Art

Multimedia electronic devices, such as televisions, mobile phones, tablet computers, computers, navigation devices, and game devices, include a display device displaying images. A display panel within the display device includes a light emitting element and a circuit to drive the light emitting element. Light emitting elements included in the display panel emit lights and generate images in response to voltages applied thereto from the circuit. The light emitting element and the circuit are being developed to improve reliability of the display panel.

### SUMMARY

The present disclosure provides a display device with improved reliability related to moisture penetration, and an electronic device including the display device.

Embodiments of the invention provide a display device including a base layer, an insulating layer disposed on the base layer and provided with a first groove defined therein to have a closed-curve shape when viewed in a plane, a light emitting element including a first electrode disposed on the insulating layer, a light emitting pattern disposed on the first electrode, and a second electrode disposed on the light emitting pattern, a pixel definition layer disposed on the insulating layer and provided with a light emitting opening defined therethrough to expose at least a portion of the first electrode and a first hole defined therethrough and overlapping the first groove when viewed in the plane, and a protruding pattern disposed on the insulating layer and directly in contact with the pixel definition layer. At least one of the first groove and the first hole surrounds the protruding pattern when viewed in the plane.

The first groove and the first hole are provided integrally with each other.

The pixel definition layer includes first tip portions protruded from ends of the first groove.

The display device further includes a first inorganic layer covering the light emitting element and the protruding pattern.

The first inorganic layer covers a side surface and a lower surface of the insulating layer, which define the first groove.

The first inorganic layer covers a side surface of the pixel definition layer, which defines the first hole, and a lower surface of the pixel definition layer.

The display device further includes an organic layer disposed on the first inorganic layer, and a portion of the organic layer is disposed inside at least one of the first groove and the first hole.

The insulating layer is further provided with a second groove defined therein, the pixel definition layer is further provided with a second hole overlapping the second groove when viewed in the plane, and the second groove and the second hole overlap the protruding pattern when viewed in the plane.

The pixel definition layer includes second tip portions protruded from ends of the second groove.

The protruding pattern covers second tip portions.

The protruding pattern is spaced apart from the insulating layer when viewed in a cross-section.

A lower surface of the protruding pattern is entirely in contact with an upper surface of the pixel definition layer.

The insulating layer is further provided with a third groove defined therein to surround the first groove when viewed in the plane.

The pixel definition layer includes a first layer disposed on the insulating layer, a second layer disposed on the first layer, and a third layer disposed on the second layer, and an end of the second layer is recessed in a direction away from a center of the first groove compared to an end of the first layer and an end of the third layer.

The first layer and the third layer include an inorganic material, and the second layer includes an organic material.

Embodiments of the invention provide a display device including a base layer, an insulating layer disposed on the base layer and provided with a first groove defined therein by removing at least a portion of the insulating layer in a thickness direction of the insulating layer, a first light emitting element disposed on the insulating layer, a second light emitting element disposed on the insulating layer and spaced apart from the first light emitting element when viewed in a plane, a protruding pattern disposed between the first light emitting element and the second light emitting element when viewed in the plane, and a pixel definition layer disposed on the insulating layer and provided with a first hole defined therethrough in the thickness direction. The protruding pattern is spaced apart from each of the first and second light emitting elements with the first groove interposed therebetween.

The insulating layer is further provided with a second groove defined therein, the pixel definition layer is further provided with a second hole overlapping the second groove when viewed in the plane, and the second groove and the second hole overlap the protruding pattern when viewed in the plane.

The protruding pattern is spaced apart from the insulating layer when viewed in a cross-section.

Embodiments of the invention provide a display device including a base layer, an insulating layer disposed on the base layer and provided with a first groove and a second groove, which are defined therein by removing at least a portion of the insulating layer in a thickness direction of the insulating layer, a light emitting element disposed on the insulating layer, a pixel definition layer disposed on the insulating layer and including first tip portions protruded from ends of the first groove and second tip portions protruded from ends of the second groove, and a protruding pattern disposed on the insulating layer and covering an upper surface, a side surface, and a lower surface of the second tip portions of the pixel definition layer.

The display device further includes a first inorganic layer which covers the light emitting element, the protruding pattern, and an upper surface, a side surface, and a lower surface of the first tip portions.

According to the above, as the lower surface of the pixel definition layer defining the first tip portion is directly coupled with the first inorganic layer, an adhesion between the pixel definition layer and the first inorganic layer is improved. As an example, the pixel definition includes the first tip portion, and the first inorganic layer is coupled not only with the side surface and the upper surface but also with the lower surface of the first tip portion of the pixel definition layer. Accordingly, the pixel definition layer and the first inorganic layer is further coupled with each other in the lower surface of the first tip portion of the pixel definition layer, and the adhesive force between the pixel definition layer and the first inorganic layer is improved. In addition, as the pixel definition layer including an inorganic material is directly coupled with the first inorganic layer including an inorganic material, the adhesive force between the pixel definition layer and the first inorganic layer is improved. Thus, defects of the pixels, which are caused by a foreign substance which enters the thin film encapsulation layer, are reduced or prevented, and an encapsulating ability of the thin film encapsulation layer is enhanced.

The second tip portion is defined in the pixel definition layer. Since the protruding pattern covers the second tip portion, an adhesive force between the protruding pattern and the pixel definition layer is improved. That is, as the pixel definition layer includes the second tip portion, the protruding pattern covers the upper surface, the side surface, and the lower surface of the second tip portion. Since the protruding pattern and the pixel definition layer are further coupled with each other in the lower surface of the second tip portion, the adhesive force between the protruding pattern and the pixel definition layer is improved. In detail, as the adhesive force is improved, the protruding pattern effectively covers the insulating layer, and thus, a width of the protruding pattern is reduced.

As the first groove recessed in the thickness direction is defined in the insulating layer and the first hole corresponding to the first groove is defined through the pixel definition layer, portions of the pixel definition layer corresponding to the protruding pattern are disconnected from portions of the pixel definition layer corresponding to the first and second light emitting elements. Accordingly, even though a foreign matter is generated when a fine metal mask (FMM) collides with the protruding pattern during an evaporation process using the fine metal mask, the foreign matter generated near the protruding pattern does not travel to the first and second light emitting elements.

As the adhesive force between the pixel definition layer and the first inorganic layer is improved and the protruding pattern has an isolated shape spaced apart from the first and second light emitting elements by the first groove and the first hole, a moisture penetration phenomenon caused by outgassing gases which infiltrate into an area where the first inorganic layer thinly covers the foreign matter (or a lower end of the foreign matter) formed on the insulating layer is reduced or prevented.

According to embodiments, the insulating layer is not provided with the second groove. That is, the protruding pattern is not formed in the insulating layer, and thus, a volume of the protruding pattern is reduced. Therefore, an amount of material used to form the protruding pattern is reduced.

As the third groove is further defined in the insulating layer, a separation distance between the protruding pattern and the first and second light emitting elements increases. Accordingly, a foreign matter generated adjacent to the protruding pattern is effectively prevented from moving to the first and second light emitting elements, and a moisture penetration phenomenon caused by outgassing gases which infiltrate into an area where the first inorganic layer thinly covers the foreign matter (or a lower end of the foreign matter) is reduced or prevented.

According to embodiments, the pixel definition layer includes the first, second, and third layers, and thus, plural tip portions are formed. The first inorganic layer covers not only the side surface and the upper surface of the first, second, and third layers but also the lower surface thereof. Since the first inorganic layer is further coupled with the lower surface of the first layer and the third layer of the pixel definition layer, the adhesive force between the pixel definition layer and the first inorganic layer is more effectively improved.

### BRIEF DESCRIPTION OF THE DRAWINGS

The above and other advantages of the present disclosure will become readily apparent by reference to the following detailed description when considered in conjunction with the accompanying drawings where:

FIG. 1 is a perspective view of a display device according to an embodiment of the present disclosure;

FIG. 2 is a cross-sectional view of a display device according to an embodiment of the present disclosure;

FIG. 3 is an enlarged cross-sectional view of a display panel according to an embodiment of the present disclosure;

FIG. 4 is a plan view of a display device according to an embodiment of the present disclosure;

FIG. 5 is a cross-sectional view of a display device taken along a line I-I′ of FIG. 4;

FIG. 6 is an enlarged view of an area AA′ of FIG. 5;

FIG. 7 is an enlarged view of an area AA′ of FIG. 5;

FIG. 8 is a cross-sectional view of a display device according to an embodiment of the present disclosure; and

FIG. 9 is an enlarged view of an area AA′ of FIG. 5.

FIG. 10 is a block diagram illustrating an electronic device according to an embodiment.

FIG. 11 is a view illustrating an example of the electronic device of FIG. 10 implemented as a smartphone.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the present disclosure, it will be understood that when an element (or area, layer, or portion) is referred to as being related to another element such as being “on”, “connected to” or “coupled to” another element or layer, it can be directly on, connected or coupled to the other element or layer or intervening elements or layers may be present. In contrast, when an element (or area, layer, or portion) is referred to as being related to another element such as being “directly on”, “directly connected to” or “directly coupled to” another element or layer, no other element or layer or intervening element or layers is present therebetween.

Like numerals refer to like elements throughout. In the drawings, the thickness, ratio, and dimension of components are exaggerated for effective description of the technical content. Within the Figures and the text of the disclosure, a reference number indicating a singular form of an element may also be used to reference a plurality of the element.

As used herein, the term “and/or” may include any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure.

The terminology used herein is for the purpose of describing particular embodiments only and is not intended to be limiting. As used herein, the singular forms, “a”, “an” and “the” are intended to include the plural forms as well, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.”

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

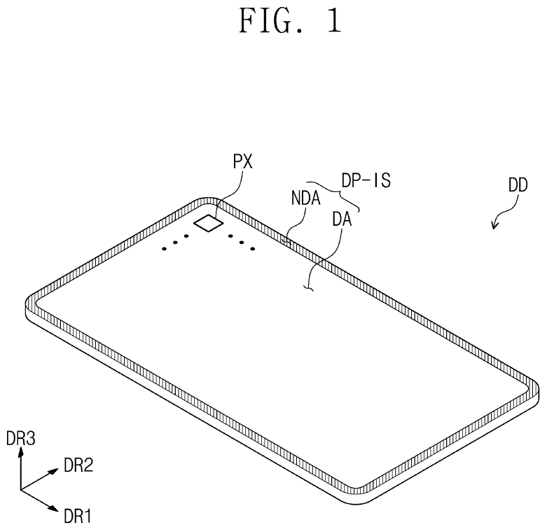

FIG. 1 is a perspective view of a display device DD according to an embodiment of the present disclosure.

The display device DD may be applied to a large-sized electronic device, such as a television set, a monitor, an outdoor billboard, etc. In addition, the display device DD may be applied to a small and medium-sized electronic device, such as a personal computer, a notebook computer, a personal digital assistant, a car navigation unit, a game unit, a smart phone, a tablet computer, a camera, etc. However, these are merely examples, and the display device DD may be applied to other electronic devices as long as they do not depart from the concept of the present disclosure.

Referring to FIG. 1, the display device DD may display an image through a display surface DP-IS, which is substantially parallel to a plane defined by a first direction DR1 and a second direction DR2 which crosses the first direction DR1, toward a third direction DR3. The image may include a still image as well as a video. The display surface DP-IS through which the image is displayed may correspond to or define a front surface of the display device DD.

The display device DD may include a display area DA and a non-display area NDA which is adjacent to the display area DA. A pixel PX provided in plural as including pixels PX may be arranged in the display area DA. The pixels PX may not be arranged in the non-display area NDA. The non-display area NDA may be defined along an edge of the display surface DP-IS, that is, an outer edge of the display device DD. The non-display area NDA may surround the display area DA in the plan view, however, this is merely an example. According to an embodiment, the non-display area NDA may be omitted or may be defined adjacent to only one side of the display area DA. FIG. 1 shows a flat display device DD as a representative example, however, the present disclosure should not be limited thereto or thereby. As an example, the display device DD may be a curved display device or a foldable display device, which refers to the property of being able to be bent from a structure which is completely bent to a structure which is bent at the scale of a few nanometers.

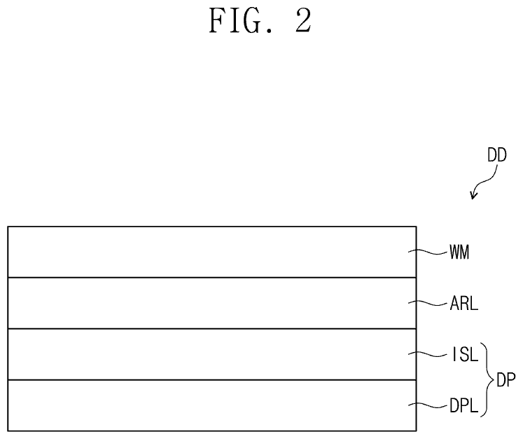

FIG. 2 is a cross-sectional view of the display device DD according to an embodiment of the present disclosure.

Referring to FIG. 2, the display device DD may include a display panel DP, an anti-reflective layer ARL as a functional layer, and a window WM. The display panel DP may include a display layer DPL as an image display layer and an input sensor layer ISL.

The display layer DPL may be a light emitting type display layer. For example, the display layer DPL may be an organic light emitting display layer, an inorganic light emitting display layer, an organic-inorganic light emitting display layer, a micro-light emitting diode (LED) display layer, a nano-LED display layer, or a quantum dot light emitting display layer.

The organic light emitting display layer may include an organic light emitting material. The quantum dot light emitting display layer may include a quantum dot and/or a quantum rod. The micro-LED display layer may include a micro light-emitting diode element, which is an ultra-small light-emitting element, and the nano-LED display layer may include a nano light-emitting diode element. Hereinafter, the organic light emitting display layer will be described as the display layer DPL.

The input sensor layer ISL may be disposed on the display layer DPL, that is, facing the display layer DPL. The input sensor layer ISL may sense an external input applied thereto from the outside (e.g., outside of the display device DD and/or the electronic device). As an example, the input sensor layer ISL may obtain information to generate the image on the display panel DP in response to an external input. The external input may be a user's input. The user's input may include a variety of external inputs, such as light, heat, or pressure applied from an input tool such as a part of user's body, pen, or the like.

The input sensor layer ISL may be formed (or provided) on the display layer DPL through successive processes in a method of providing the display device DD. In this case, the input sensor layer ISL may be disposed directly on the display layer DPL. In the present disclosure, the expression “A component A is disposed directly on a component B.” means that no intervening elements are present between the component A and the component B. That is, an adhesive member may not be disposed between the input sensor layer ISL and the display layer DPL.

The anti-reflective layer ARL may be disposed on the input sensor layer ISL. The anti-reflective layer ARL may reduce a reflectance of the display device DD with respect to an external light. According to an embodiment, the anti-reflective layer ARL may selectively transmit a light exiting from the display panel DP. The anti-reflective layer ARL may be disposed directly on the input sensor layer ISL through successive processes in a method of providing the display device DD.

The window WM may be disposed on the anti-reflective layer ARL. The window WM and the anti-reflective layer ARL may be coupled to each other by an adhesive layer (not shown). The adhesive layer may be a pressure sensitive adhesive (PSA) film or an optically clear adhesive (OCA).

The window WM may include at least one base layer. The base layer may be a glass substrate or a synthetic resin film. The window WM may have a multi-layer structure. The window WM may include a thin film glass substrate and a synthetic resin film disposed on the thin film glass substrate. The thin film glass substrate and the synthetic resin film may be coupled to each other by an adhesive layer, and the adhesive layer and the synthetic resin film may be separated from the thin film glass substrate to be replaced. The window WM may be optically transmissive such that an image generated within the display device DD is viewable from outside the display device DD.

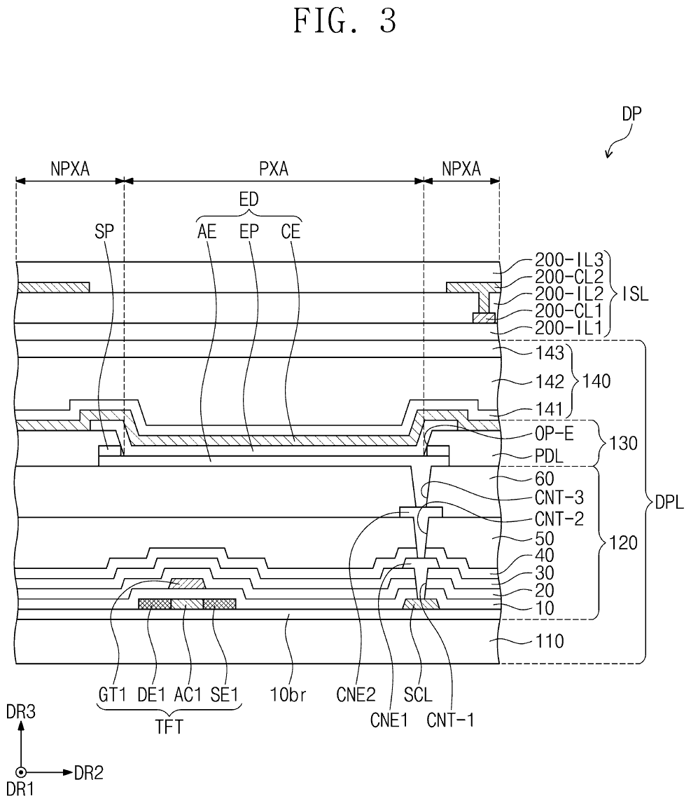

FIG. 3 is a cross-sectional view of the display panel DP according to an embodiment of the present disclosure.

FIG. 3 shows a cross-section corresponding to one light emitting area PXA and a peripheral area NPXA around the one light emitting area PXA. The light emitting area PXA and the peripheral area NPXA may be disposed within the display area DA, such as being applied to a pixel PX and/or a light emission area of the display device DD. FIG. 3 shows only one light emitting area PXA, however, the light emitting area PXA may be provided in plural.

FIG. 3 shows a light emitting element ED and a transistor TFT which is connected to the light emitting element ED. The transistor TFT may be one of a plurality of transistors included in a driving circuit of the pixels PX (refer to FIG. 1). In the present embodiment, the transistor TFT will be described as a silicon transistor, however, according to an embodiment, the transistor TFT may be a metal oxide transistor.

Referring to FIG. 3, the display panel DP may include the display layer DPL and the input sensor layer ISL facing each other. The display layer DPL may include a base layer 110, a circuit layer 120, a light emitting element layer 130, and a thin film encapsulation layer 140.

The base layer 110 may provide a base surface on which the circuit layer 120 is disposed. The base layer 110 as a substrate may be a rigid substrate or a flexible substrate which is bendable, foldable, or rollable. The base layer 110 may be a glass substrate, a metal substrate, or a polymer substrate, however, it should not be limited thereto or thereby. According to an embodiment, the base layer 110 may be an inorganic layer, an organic layer, or a composite material layer.

The base layer 110 may have a multi-layer structure along a thickness direction (e.g., the third direction DR3). For instance, the base layer 110 may include a first synthetic resin layer, an inorganic layer having a single-layer or multi-layer structure, and a second synthetic resin layer disposed on the inorganic layer having the single-layer or multi-layer structure. Each of the first and second synthetic resin layers may include a polyimide-based resin, however, it should not be particularly limited.

The circuit layer 120 may be disposed on the base layer 110. The circuit layer 120 may include an insulating layer, a semiconductor pattern, a conductive pattern, a signal line, and the driving circuit of the pixels PX. As an example, the circuit layer 120 may include a buffer layer 10br, first, second, third, fourth, fifth, and sixth insulating layers 10, 20, 30, 40, 50, and 60 a signal transmission area SCL, and a plurality of connection electrodes like CNE1 and CNE2.

The buffer layer 10br may be disposed on the base layer 110. The buffer layer 10br may prevent metal atoms or impurities from being diffused to the semiconductor pattern disposed thereon from the base layer 110. The semiconductor pattern may include an active area AC1 of the transistor TFT. A rear surface metal layer (not shown) may be further disposed between the base layer 110 and the buffer layer 10br. The rear surface metal layer may be disposed under the transistor TFT, and the rear surface metal layer may prevent the external light from reaching the transistor TFT.

The semiconductor pattern may be disposed on the buffer layer 10br. The semiconductor pattern may include a silicon semiconductor. As an example, the silicon semiconductor may include amorphous silicon or polycrystalline silicon. For example, the semiconductor pattern may include low temperature polycrystalline silicon.

The semiconductor pattern may include a first region having a relatively high conductivity (e.g., electrical conductivity) and a second region having a relatively low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or a region doped at a concentration lower than that of the first region.

The first region may have a conductivity greater than that of the second region and may substantially serve as an electrode or a signal line. The second region may substantially correspond to an active area (or a channel) of the transistor. In other words, a portion of the semiconductor pattern may be the active area of the transistor, another portion of the semiconductor pattern may be a source or a drain of the transistor, and the other portion of the semiconductor pattern may be a connection electrode or a connection signal line.

The transistor TFT may include a source area SE1 (or a source), the active area AC1 (or a channel), a drain area DE1 (or a drain), and a gate GT1. The source area SE1, the active area AC1, and the drain area DE1 of the transistor TFT may be formed from the semiconductor pattern as respective areas thereof. The source area SE1 and the drain area DE1 may extend in opposite directions to each other from the active area AC1 in a cross-section.

FIG. 3 shows a portion of the signal transmission area SCL formed using the semiconductor pattern. Although not shown in FIG. 3, the signal transmission area SCL may be connected to the drain area DE1 of the transistor TFT when viewed in a plane. In an embodiment, the semiconductor pattern and the signal transmission area SCL may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The first insulating layer 10 may be disposed on the buffer layer 10br. The first insulating layer 10 may commonly overlap the pixels PX and may cover the semiconductor pattern. As an example, the first insulating layer 10 may cover the source area SE1, the active area AC1, the drain area DE1, and the signal transmission area SCL of the transistor TFT disposed on the buffer layer 10br.

The first insulating layer 10 may include an inorganic layer and/or an organic layer and may have a single-layer or multi-layer structure. The inorganic layer may include at least one of aluminum oxide, titanium oxide, silicon oxide, silicon nitride, silicon oxynitride, zirconium oxide, and hafnium oxide. In the present embodiment, the first insulating layer 10 may have a single-layer structure of a silicon oxide layer. An insulating layer of the circuit layer 120 described later may be an inorganic layer and/or an organic layer and may have a single-layer or multi-layer structure as well as the first insulating layer 10. The inorganic layer may include at least one of the above-mentioned materials, however, it should not be limited thereto or thereby.

The gate GT1 of the transistor TFT may be disposed on the first insulating layer 10. The gate GT1 may be a portion of a metal pattern or a metal material layer. The gate GT1 may overlap the active area AC1. The gate GT1 may be used as a mask in a process of doping the semiconductor pattern in a method of providing the display device DD.

The gate GT1 may include titanium (Ti), silver (Ag), an alloy including silver (Ag), molybdenum (Mo), an alloy including molybdenum (Mo), aluminum (Al), an alloy including aluminum (Al), aluminum nitride (AIN), tungsten (W), tungsten nitride (WN), copper (Cu), indium tin oxide (ITO), indium zinc oxide (IZO), or the like, however, it should not be particularly limited.

The second insulating layer 20 may be disposed on the first insulating layer 10 and may cover the gate GT1. The second insulating layer 20 may commonly overlap the pixels. The second insulating layer 20 may be an inorganic layer and/or an organic layer and may have a single-layer or multi-layer structure. The second insulating layer 20 may include at least one of silicon oxide, silicon nitride, and silicon oxynitride. In the present embodiment, the second insulating layer 20 may have a multi-layer structure of a silicon oxide layer and a silicon nitride layer.

The third insulating layer 30 may be disposed on the second insulating layer 20. The third insulating layer 30 may have a single-layer structure or a multi-layer structure. As an example, the third insulating layer 30 may have the multi-layer structure of a silicon oxide layer and a silicon nitride layer.

A first connection electrode CNE1 may be disposed on the third insulating layer 30. The first connection electrode CNE1 may be connected to the signal transmission area SCL via a contact hole CNT-1 (e.g., a first contact hole) defined penetrating through the first, second, and third insulating layers 10, 20, and 30.

The fourth insulating layer 40 may be disposed on the third insulating layer 30 and may cover the first connection electrode CNE1. The fourth insulating layer 40 may have a single-layer structure of a silicon oxide layer.

The fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 via a contact hole CNT-2 (e.g., a second contact hole) defined penetrating through the fourth insulating layer 40 and the fifth insulating layer 50.

A sixth insulating layer 60 may be disposed on the fifth insulating layer 50 and may cover the second connection electrode CNE2. The sixth insulating layer 60 may be an organic layer. The stack structure of the first to sixth insulating layers 10 to 60 is merely an example, and additional conductive layer and insulating layer may be disposed in addition to the first to sixth insulating layers 10 to 60. The sixth insulating layer 60 may be referred to as an insulating layer in the following descriptions. In embodiments, one or more among the layers 10, 20, 30, 40, 50 and 60 may together be referred to as an insulating layer.

The light emitting element layer 130 may be disposed on the circuit layer 120. The light emitting element layer 130 may include the light emitting element ED, a pixel definition layer PDL, and a sacrificial pattern SP.

The light emitting element ED may include an organic light emitting element, an inorganic light emitting element, an organic-inorganic light emitting element, a quantum dot light emitting element, a micro-LED element, or a nano-LED element, however, the light emitting element ED should not be particularly limited. The light emitting element ED may include various embodiments as long as a light is generated or the amount of light in response to an electrical signal is controlled. In an embodiment, the light emitting element ED emits light and/or an amount of light emitted by the transistor TFT which is connected to the light emitting element ED.

The light emitting element ED may include a first electrode (or anode) AE, a light emitting pattern EP, and a second electrode (or cathode) CE. The first electrode AE may be disposed on the sixth insulating layer 60. The first electrode AE may be connected to the second connection electrode CNE2 via a contact hole CNT-3 (e.g., a third contact hole) defined penetrating through the sixth insulating layer 60.

The first electrode AE may be a transmissive electrode, a semi-transmissive electrode, or a reflective electrode. The first electrode AE may include a reflective layer formed of Ag, Mg, Al, Pt, Pd, Au, Ni, Nd, Ir, Cr, or compounds thereof and a transparent or semi-transparent electrode layer formed on the reflective layer. The transparent or semi-transparent electrode layer may include at least one selected from indium tin oxide (ITO), indium zinc oxide (IZO), indium gallium zinc oxide (IGZO), zinc oxide (ZnO), indium oxide (In₂O₃), and aluminum-doped zinc oxide (AZO). For instance, the first electrode AE may have a stack structure of ITO/Ag/ITO.

The pixel definition layer PDL may be disposed on the sixth insulating layer 60. The pixel definition layer PDL may have a light absorbing property. For example, the pixel definition layer PDL may have a black color. The pixel definition layer PDL may include a black coloring agent. The black coloring agent may include a black dye or a black pigment. The black coloring agent may include a metal material, such as carbon black, chromium, or an oxide thereof.

A solid portion of the pixel definition layer PDL may cover a portion of the first electrode AE. As an example, a light emitting opening OP-E may be defined through the solid potion (or material layer) of the pixel definition layer PDL to expose a portion of the first electrode AE. The light emitting opening OP-E of the pixel definition layer PDL may define the light emitting area PXA.

Although not shown in figures, a hole control layer may be further disposed between the first electrode AE and the light emitting pattern EP. The hole control layer may include a hole transport layer and/or a hole injection layer. An electron control layer may be disposed between the light emitting pattern EP and the second electrode CE. The electron control layer may further include an electron transport layer and/or an electron injection layer.

The sacrificial pattern SP may be disposed between the anode AE and the pixel definition layer PDL. As an example, the sacrificial pattern SP may be disposed on an upper surface of the anode AE which faces the pixel definition layer PDL. The sacrificial pattern SP may include amorphous transparent conductive oxide. According to the present embodiment, the upper surface of the anode AE which faces (or overlaps) a lower surface of the pixel definition layer PDL may be spaced apart from the pixel definition layer PDL owing to the sacrificial pattern SP interposed therebetween when viewed in a cross-section. Thus, damage to the anode AE may be prevented in a process of forming the light emitting opening OP-E in a method of providing a display device DD.

The thin film encapsulation layer 140 as an encapsulation layer may be disposed on the light emitting element layer 130. The thin film encapsulation layer 140 may protect the light emitting element layer 130 from moisture, oxygen, and a foreign substance such as dust particles. The thin film encapsulation layer 140 may include a first inorganic layer 141 as an inorganic encapsulation layer, an organic layer 142 as an organic encapsulation layer, and a second inorganic layer 143, which are sequentially stacked along the thickness direction, however, layers forming the thin film encapsulation layer 140 should not be limited thereto or thereby.

The first and second inorganic layers 141 and 143 may protect the light emitting element layer 130 from moisture and oxygen, and the organic layer 142 may protect the light emitting element layer 130 from the foreign substance such as dust particles. The first and second inorganic layers 141 and 143 may include a silicon nitride layer, a silicon oxynitride layer, a silicon oxide layer, a titanium oxide layer, or an aluminum oxide layer.

The organic layer 142 may include an acrylic-based organic layer, however, it should not be particularly limited.

The input sensor layer ISL may be disposed on the display layer DPL. The input sensor layer ISL may be referred to as a sensor layer, an input sensing layer, or an input sensing panel. The input sensor layer ISL may include a base insulating layer 200-IL1, a first conductive layer 200-CL1, a sensing insulating layer 200-IL2, a second conductive layer 200-CL2, and a cover layer 200-IL3.

The base insulating layer 200-IL1 may be disposed directly on the display layer DPL. The base insulating layer 200-IL1 may be an inorganic layer including at least one of silicon nitride, silicon oxynitride, and silicon oxide. According to an embodiment, the base insulating layer 200-IL1 may be an organic layer including an epoxy resin, an acrylic resin, or an imide-based resin. The base insulating layer 200-IL1 may have a single-layer structure or a multi-layer structure of layers stacked in the third direction DR3.

Each of the first conductive layer 200-CL1 and the second conductive layer 200-CL2 may have a single-layer structure or a multi-layer structure of layers stacked in the third direction DR3. Each of the first conductive layer 200-CL1 and the second conductive layer 200-CL2 may include a sensing pattern, which has a mesh structure, or a bridge pattern

The conductive layer having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), indium zinc tin oxide (IZTO), or the like. In addition, the transparent conductive layer may include conductive polymer such as PEDOT, metal nanowire, graphene, or the like.

The conductive layer having the multi-layer structure may include metal layers. The metal layers may have a three-layer structure of titanium/aluminum/titanium. The conductive layer having the multi-layer structure may include at least one metal layer and at least one transparent conductive layer.

The sensing insulating layer 200-IL2 may be disposed between the first conductive layer 200-CL1 and the second conductive layer 200-CL2. The cover layer 200-IL3 may be disposed on the sensing insulating layer 200-IL2 and may cover the second conductive layer 200-CL2. The cover layer 200-IL3 may reduce or remove a probability of damage to the second conductive layer 200-CL2 in a subsequent process in a method of providing the display device DD.

The sensing insulating layer 200-IL2 and the cover layer 200-IL3 may include an inorganic layer. The inorganic layer may include at least one of aluminum oxide, titanium oxide, silicon oxide, silicon nitride, silicon oxynitride, zirconium oxide, and hafnium oxide.

According to an embodiment, the sensing insulating layer 200-IL2 and the cover layer 200-IL3 may include an organic layer. The organic layer may include at least one of an epoxy-based resin, a urethane-based resin, a cellulose-based resin, a siloxane-based resin, a polyimide-based resin, a polyamide-based resin, and a perylene-based resin.

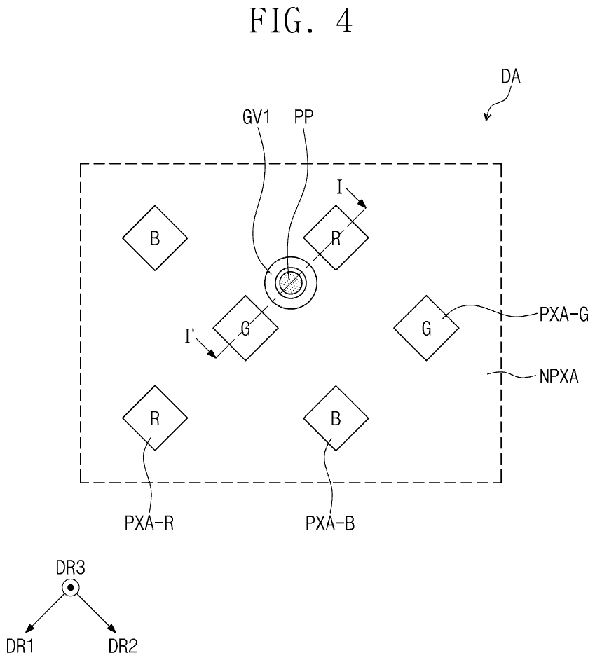

FIG. 4 is a plan view of a portion of the display area DA of the display panel DP according to an embodiment of the present disclosure. FIG. 4 is a plan view showing the display area DA when viewed from above the display surface DP-IS (refer to FIG. 1) parallel to the display area DA. FIG. 4 shows an arrangement of light emitting areas PXA-R, PXA-G, and PXA-B, and a protruding pattern PP and a first groove GV1 which are defined in (or by) the sixth insulating layer 60 (refer to FIG. 3).

Referring to FIG. 4, the display area DA may include first, second, and third light emitting areas PXA-R, PXA-G, and PXA-B and the peripheral area NPXA which surrounds the first, second, and third light emitting areas PXA-R, PXA-G, and PXA-B.

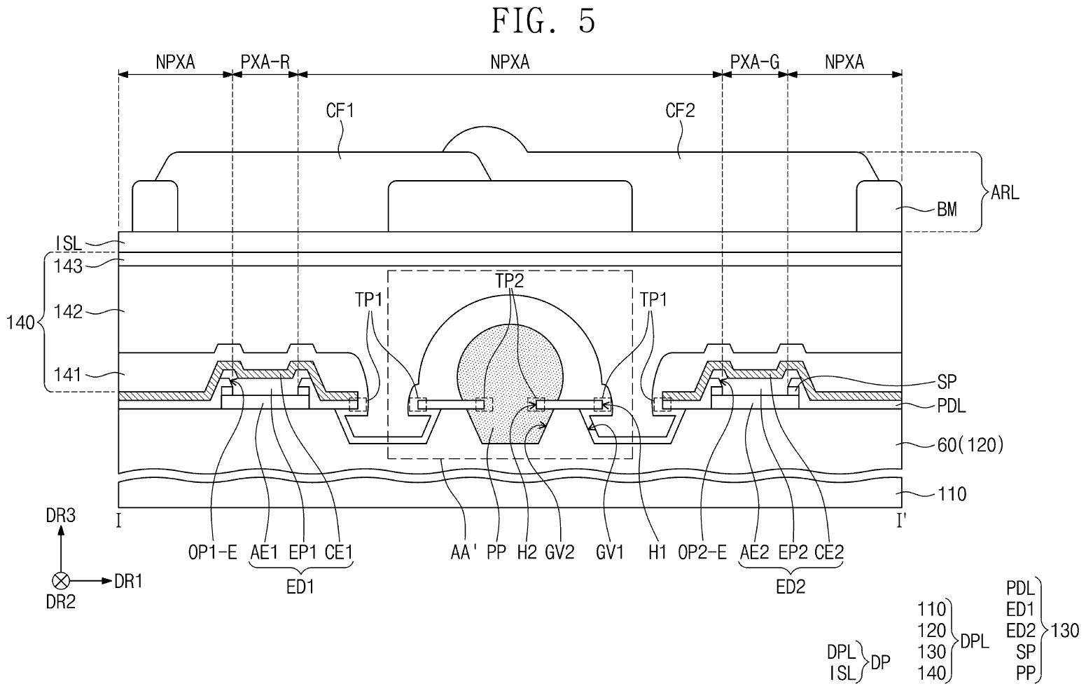

The first, second, and third light emitting areas PXA-R, PXA-G, and PXA-B may respectively correspond to areas (e.g., planar areas) from which lights provided from light emitting elements ED1 and ED2 (refer to FIG. 5) are emitted. The first, second, and third light emitting areas PXA-R, PXA-G, and PXA-B may be distinguished from each other by colors of the lights emitted outward from the display area DA (refer to FIG. 1).

The first, second, and third light emitting areas PXA-R, PXA-G, and PXA-B may respectively provide first, second, and third color lights having colors different from each other. As an example, the first color light may be a red light, the second color light may be a green light, and the third color light may be a blue light. However, the first, second, and third color lights should not be limited thereto or thereby.

Each of the first, second, and third light emitting areas PXA-R, PXA-G, and PXA-B may be defined as an area through which the upper surface of the anode AE is exposed to outside the pixel definition layer PDL by the light emitting opening OP-E defined by the pixel definition layer PDL described later. The peripheral area NPXA may define a boundary between the first, second, and third light emitting areas PXA-R, PXA-G, and PXA-B and may prevent a mixture of the colors of the lights between the first, second, and third light emitting areas PXA-R, PXA-G, and PXA-B. The peripheral area NPXA may form a boundary with the light emitting areas.

Meanwhile, FIG. 4 shows a representative example of the arrangement of the first, second, and third light emitting areas PXA-R, PXA-G, and PXA-B, and the arrangement of the first, second, and third light emitting areas PXA-R, PXA-G, and PXA-B may be changed in various ways and should not be particularly limited. The first, second, and third light emitting areas PXA-R, PXA-G, and PXA-B may be arranged in a pentile pattern (PENTILE™) in the plan view. According to an embodiment, the first, second, and third light emitting areas PXA-R, PXA-G, and PXA-B may be arranged in a stripe pattern or a diamond pattern (Diamond Pixel™) in the plan view.

Meanwhile, the shape (e.g., the planar shape), size (e.g., planar dimension or planar area), and arrangement of the first, second, and third light emitting areas PXA-R, PXA-G, and PXA-B in the display area DA may be designed in various ways depending on the colors of the emitted lights, the size of the display area DA, and the configuration of the display area DA, and they should not be limited to the embodiment shown in FIG. 4. Each of the first, second, and third light emitting areas PXA-R, PXA-G, and PXA-B may be provided in plural and may be repeatedly arranged in a predetermined arrangement within the display area DA.

The protruding pattern PP may be disposed in the peripheral area NPXA. As an example, the protruding pattern PP may be disposed between the light emitting areas PXA-R, PXA-G, and PXA-B. That is, the protruding pattern PP may be disposed between the light emitting elements ED1 and ED2 (refer to FIG. 5). FIG. 4 shows the protruding pattern PP disposed between the first light emitting area PXA-R and the second light emitting area PXA-G as a representative example, however, the present disclosure should not be limited thereto or thereby. As an example, the protruding pattern PP may be disposed between the second light emitting area PXA-G and the third light emitting area PXA-B or may be disposed between the third light emitting area PXA-B and the first light emitting area PXA-R.

In addition, FIG. 4 shows the structure in which one protruding pattern PP is disposed between six light emitting areas PXA-R, PXA-G, and PXA-B as a representative example, however, the number of the protruding patterns PP within the peripheral area NPXA should not be limited thereto or thereby as long as damage to the pixel definition layer PDL may be prevented in an evaporation process using a fine metal mask (FMM) during a method of providing the display device DD.

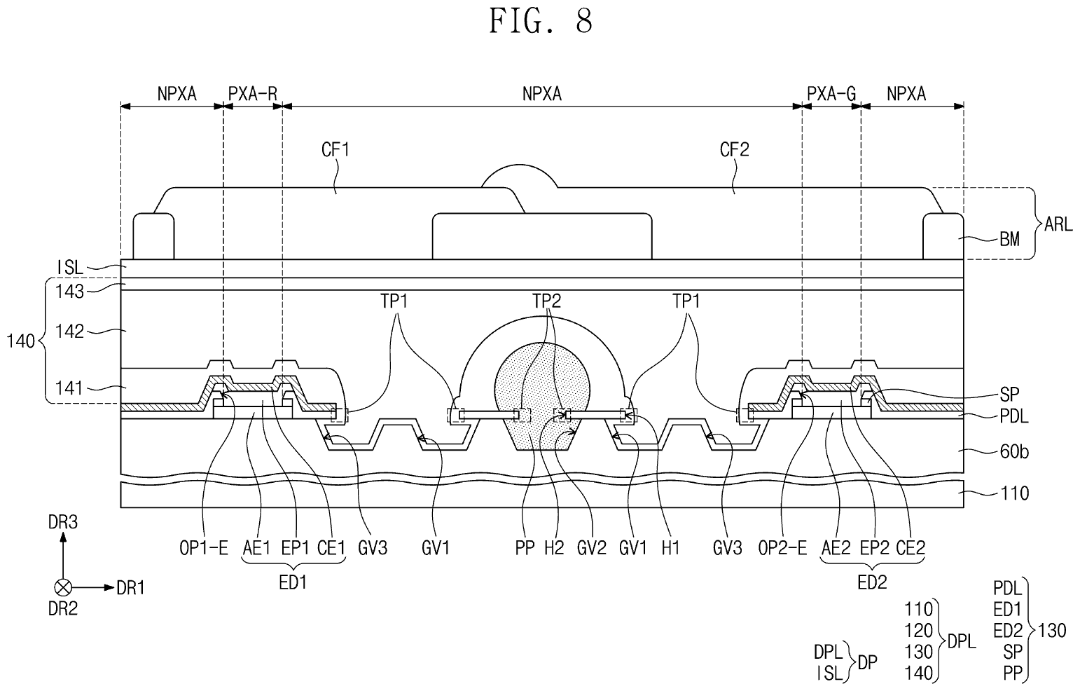

The first groove GV1 may be defined in the sixth insulating layer 60. The first groove GV1 may have a closed-curve shape when viewed in the plane. The first groove GV1 may surround the protruding pattern PP when viewed in the plane. FIG. 4 shows one first groove GV1 surrounding the protruding pattern PP as a representative example, however, a plurality of grooves may be defined in the sixth insulating layer 60. Details of the grooves will be described in detail with reference to FIG. 8. A planar shape of the first groove GV1 may correspond to a planar shape of the protruding pattern PP, without being limited thereto. In an embodiment, the shape of the first groove GV1 may extend parallel to an outer edge of the protruding pattern. The planar shape may be a curved shape, a rectilinear shape, etc.

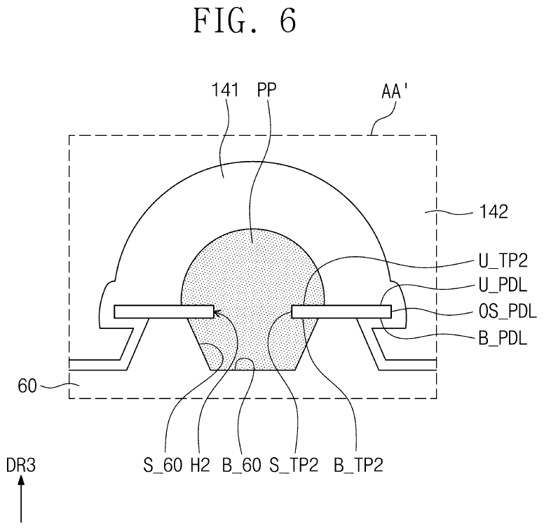

FIG. 5 is a cross-sectional view of a portion of the display device DD (refer to FIG. 1) taken along a line I-I′ of FIG. 4. FIG. 6 is an enlarged view of an area AA′ of FIG. 5.

In FIGS. 5 and 6, the same reference numerals denote the same elements in FIGS. 2 and 3, and thus, detailed descriptions of the same elements will be omitted. For the sake of explanation, FIG. 5 shows the display device DD from which the window WM (refer to FIG. 3) is omitted. Descriptions on each of the first and second light emitting elements ED1 and ED2 of FIG. 5 may be substantially the same as the descriptions on the light emitting element ED of FIG. 3.

Referring to FIGS. 5 and 6, the display layer DPL may include the base layer 110, the circuit layer 120, the light emitting element layer 130, and the thin film encapsulation layer 140. In FIG. 5, components of the circuit layer 120 except the sixth insulating layer (or the insulating layer) 60 are omitted.

Grooves such as the first groove GV1 and a second groove GV2 may be defined in the sixth insulating layer 60. In an embodiment of a method of providing the display device DD, the grooves may be provided in an insulating material layer of the sixth insulating layer 60 by removing at least portions of the sixth insulating layer 60 in a thickness direction, e.g., the third direction DR3, of the sixth insulating layer 60. A thickness portion which is removed may be a partial thickness of the insulating material layer, that is, the grooves may not penetrate the insulating material layer. In detail, the first groove GV1 and the second groove GV2 defined extending into the sixth insulating layer 60 such as by providing recesses extended from an upper surface of the sixth insulating layer 60 which is furthest from the base layer 110 in a direction opposite to the third direction DR3 (e.g., in a direction towards the base layer 110).

The first groove GV1 and the second groove GV2 may each be defined by a side surface S_60 together with a lower surface B_60 of the sixth insulating layer 60. The lower surface B_60 may be defined between the upper surface and a bottom surface which is closest to the base layer 110), along the third direction DR3. The sixth insulating layer 60 may include the side surface S_60 provided in plural including side surfaces and the lower surface B_60 provided in plural including lower surfaces. The lower surfaces may respectively define a bottom of a respective groove among the grooves.

The light emitting element layer 130 may include the first light emitting element ED1, the second light emitting element ED2, the pixel definition layer PDL, the sacrificial pattern SP, and the protruding pattern PP.

The first light emitting element ED1 may include a first anode AE1, a first light emitting pattern EP1, and a first cathode CE1. The second light emitting element ED2 may include a second anode AE2, a second light emitting pattern EP2, and a second cathode CE2.

The first anode AE1 may be disposed on the sixth insulating layer 60, the first light emitting pattern EP1 may be disposed on the first anode AE1, and the first cathode CE1 may be disposed on the first light emitting pattern EP1. The second anode AE2 may be disposed on the sixth insulating layer 60, the second light emitting pattern EP2 may be disposed on the second anode AE2, and the second cathode CE2 may be disposed on the second light emitting pattern EP2.

The first and second anodes AE1 and AE2 may include a plurality of layers containing ITO or Ag. As an example, the first and second anodes AE1 and AE2 may include a layer (hereinafter, referred to as a lower ITO layer) containing ITO, a layer (hereinafter, referred to as an Ag layer) disposed on the lower ITO layer and containing Ag, and a layer (hereinafter, referred to as upper ITO layer) disposed on the Ag layer and containing ITO.

The first light emitting pattern EP1 may be disposed on the first anode AE1. The second light emitting pattern EP2 may be disposed on the second anode AE2. The first and second light emitting patterns EP1 and EP2 may be disposed in first and second light emitting openings OP1-E and OP2-E, respectively. As an example, the first light emitting pattern EP1 may be disposed in the first light emitting opening OP1-E, and the second light emitting pattern EP2 may be disposed in the second light emitting opening OP2-E.

The first and second cathodes CE1 and CE2 may include a variety of materials such as a metal, a transparent conductive oxide (TCO), or a conductive polymer material as long as the first and second cathodes CE1 and CE2 have a conductivity. As an example, the first and second cathodes CE1 and CE2 may include silver (Ag), magnesium (Mg), lead (Pb), copper (Cu), or compounds thereof.

The pixel definition layer PDL may be disposed on the sixth insulating layer 60. The pixel definition layer PDL may be provided with the first light emitting opening OP1-E, the second light emitting opening OP2-E, a first hole H1, and a second hole H2, which are defined therethrough. That is each of the first light emitting opening OP1-E as a first emission opening, the second light emitting opening OP2-E as a second emission opening, the first hole H1 as a first light non-emission area, and the second hole H2 as a second light non-emission area each defined in a pixel defining layer penetrate through a complete thickness of a solid pixel defining (material) layer to define the pixel definition layer together with the solid pixel defining (material) layer. The pixel definition layer PDL may include inner side surfaces which respectively define the first light emitting opening OP1-E, the second light emitting opening OP2-E, the first hole H1, and the second hole H2.

At least a portion of the first anode AE1 may be exposed to outside the pixel definition layer PDL through the first light emitting opening OP1-E, and at least a portion of the second anode AE2 may be exposed to outside the pixel definition layer PDL through the second light emitting opening OP2-E. The first hole H1 may be defined by a side surface OS_PDL (e.g., an inner side surface) of the pixel definition layer PDL. The first hole H1 may overlap the first groove GV1 when viewed in the plane, and the second hole H2 may overlap the second groove GV2 when viewed in the plane. The first groove GV1 and the first hole H1 may be provided integrally with each other to define an opening (e.g., a first opening), and the second groove GV2 and the second hole H2 may be provided integrally with each other to define an opening (e.g., a second opening). As being integral (e.g., continuous, overlapping, etc.), the first groove GV1 may be exposed to outside the pixel definition layer PDL by the first hole H1. Similarly, the second groove GV2 may be exposed to outside the pixel definition layer PDL by the second hole H2

The pixel definition layer PDL may include first tip portions TP1 as first tips protruded further than the side surface S_60 of the sixth insulating layer 60 which defines the first groove GV1. The first tip portions TP1 may extend from opposite sides of the first groove GV1 toward a center of the first groove GV1, respectively. In addition, the pixel definition layer PDL may include second tip portions TP2 as second tips protruded further than the side surface S_60 of the sixth insulating layer 60 which defines the second groove GV2. The second tip portions TP2 may extend from opposite sides of the second groove GV2 toward a center of the second groove GV2, respectively.

The protruding pattern PP may be disposed on the sixth insulating layer 60. In detail, a portion of the protruding pattern PP may be disposed on the sixth insulating layer 60, and the other portion of the protruding pattern PP may be disposed on the pixel definition layer PDL. The other portion of the protruding pattern PP may be directly in contact with the pixel definition layer PDL. An upper surface of the protruding pattern PP may have a hemispherical shape, however, this is merely an example. The protruding pattern PP may have a polygonal, circular, semicircular, or irregular shape when viewed in the cross-section.

The protruding pattern PP may include an organic material. As an example, the protruding pattern PP may include polyimide (PI), however, this is merely an example. Materials for the protruding pattern PP should not be limited thereto or thereby as long as the protruding pattern PP has shapes of FIGS. 5 to 9.

When viewed in the plane, the protruding pattern PP may be spaced apart from the first light emitting element ED1 with the first groove GV1 interposed therebetween and may be spaced apart from the second light emitting element ED2 in a direction along the sixth insulating layer 60, with the first groove GV1 interposed therebetween. That is, the protruding pattern PP may be formed in the closed-curve shape of the first groove GV1 when viewed in the plane.

The protruding pattern PP may overlap the second groove GV2 of the sixth insulating layer 60 and the second hole H2 of the pixel definition layer PDL when viewed in the plane. In detail, the protruding pattern PP may be disposed inside the second groove GV2 and/or inside the second hole H2. The protruding pattern PP may extend from inside the second groove GV2 and through the second hole H2 to cover the second tip portions TP2 overlapping the second groove GV2. As an example, the protruding pattern PP may cover an upper surface U_TP2 of the second tip portions, a side surface S_TP2 of the second tip portions, and a lower surface B_TP2 of the second tip portions of the pixel definition layer PDL. In addition, the protruding pattern PP may cover a side surface S_60 and a lower surface B_60 of the sixth insulating layer 60.

The first groove GV1 may surround the protruding pattern PP when viewed in the plane. The first hole H1 may overlap the first groove GV1 when viewed in the plane. That is, the first hole H1 may surround the protruding pattern PP when viewed in the plane. The term “in the plane” refers to a state of viewing the plane defined by the first direction DR1 and the second direction DR2 from above, such as along the third direction DR3.

The thin film encapsulation layer 140 may include the first inorganic layer 141 disposed on the light emitting element layer 130, the organic layer 142 disposed on the first inorganic layer 141, and the second inorganic layer 143 disposed on the organic layer 142.

The first inorganic layer 141 may cover the first light emitting element ED1, the second light emitting element ED2, and the protruding pattern PP. In detail, the first inorganic layer 141 may cover the first cathode CE1 of the first light emitting element ED1 and may cover the side surface S_60 and the lower surface B_60 of the sixth insulating layer, which define the first groove GV1. The first inorganic layer 141 may cover an upper surface U_PDL, a lower surface B_PDL, and the side surface OS_PDL of the pixel definition layer PDL, which together define the first hole H1. In addition, the first inorganic layer 141 may cover the protruding pattern PP and the second cathode CE2 of the second light emitting element ED2.

A portion of the organic layer 142 may be disposed inside the first groove GV1 or inside the first hole H1. The organic layer 142 may be disposed inside the first groove GV1 or inside the first hole H1 to fill a volume of the first groove GV1 and the first hole H1. The organic layer 142 may provide a flat upper surface which is furthest from the insulating layer (e.g., the sixth insulating layer 60).

The anti-reflective layer ARL may be disposed on the display panel DP. The anti-reflective layer ARL may include a light blocking pattern BM, a first color filter CF1, and a second color filter CF2. The light blocking pattern BM of a light blocking layer, and the first color filter CF1 and a second color filter CF2 of a color filter layer, may together define the anti-reflective layer ARL as a light control layer, a color control layer, etc. A thickness portion of each of the light blocking pattern BM, the first color filter CF1 and a second color filter CF2 may be coplanar with each other.

The light blocking pattern BM may be disposed on the input sensor layer ISL. The light blocking pattern BM may be a layer having a black color and may include a black coloring agent. The black coloring agent may include a black dye or a black pigment. The black coloring agent may include a metal material, such as carbon black, chromium, or an oxide thereof. However, this is merely an example, and materials for the light blocking pattern BM should not be particularly limited as long as the materials absorb lights.

The light blocking pattern BM may prevent the external light from being reflected by the first conductive layer 200-CL1 (refer to FIG. 3) and the second conductive layer 200-CL2 (refer to FIG. 3).

The first color filter CF1 and the second color filter CF2 may correspond to the first and second light emitting elements ED1 and ED2, respectively, may transmit lights generated by the first and second light emitting elements ED1 and ED2, respectively, and may block light in certain wavelength ranges among the external light. The first color filter CF1 may transmit the first color, and the second color filter CF2 may transmit the second color. The second color may be different from the first color. As an example, the first color may be a red color, and the second color may be a green color. The first color filter CF1 and the second color filter CF2 may reduce the reflection of the external light, which is caused by the first and second anodes AE1 and AE2 or the first and second cathodes CE1 and CE2.

A portion of the first color filter CF1 together with a portion of the second color filter CF2 may overlap the peripheral area NPXA. That is, the portion of the first color filter CF1 and the portion of the second color filter CF2 may be disposed on the light blocking pattern BM to provide a multi-layered structure of the anti-reflective layer ARL.

According to the present disclosure, as the lower surface B_PDL of the pixel definition layer PDL which is defined by the first tip portion TP1 is directly coupled with the first inorganic layer 141, an adhesive force between the pixel definition layer PDL and the first inorganic layer 141 may be improved. As an example, as the pixel definition layer PDL includes the first tip portion TP1, the first inorganic layer 141 may be coupled not only with the side surface OS_PDL and the upper surface U_PDL of the pixel definition layer PDL but also with the lower surface B_PDL of the first tip portion TP1 of the pixel definition layer PDL. Accordingly, the pixel definition layer PDL and the first inorganic layer 141 may be further coupled with each other at the lower surface B_PDL of the first tip portion TP1 of the pixel definition layer PDL, and thus, the adhesive force between the pixel definition layer PDL and the first inorganic layer 141 may be improved. In addition, as the pixel definition layer PDL including the inorganic material is directly coupled with the first inorganic layer 141 including the inorganic material, the adhesive force between the pixel definition layer PDL and the first inorganic layer 141 may be improved. Therefore, damage to the pixels PX which is due to a foreign substance which enters the thin film encapsulation layer 140 may be prevented, and an encapsulating ability of the thin film encapsulation layer 140 may be improved.

In an embodiment, an An electronic device includes a display panel DP which generates an image, and the display panel includes a base layer 110, an insulating layer (e.g., the sixth insulating layer 60) which is on the base layer 110 and defines a first groove GV1 therein a light emitting element on the insulating layer, a pixel definition layer PDL which is on the insulating layer and defines each of a light emitting opening which exposes the first electrode to outside the pixel definition layer PDL, a first hole H1 which is adjacent to the light emitting opening and overlaps the first groove GV1, and a first tip portion TP1 which overlaps the first groove GV1, and a layer (e.g., the first inorganic layer 141) which is on the light emitting element and contacts an upper surface, a side surface and a lower surface of the first tip portion TP1.

The second tip portions TP2 may be defined in the pixel definition layer PDL. Since the protruding pattern PP covers the second tip portions TP2 at the second groove GV2, the adhesive force between the protruding pattern PP and the pixel definition layer PDL may be improved. That is, as the pixel definition layer PDL includes the second tip portions TP2, the protruding pattern PP may cover the upper surface U_TP2 of the second tip portions, the side surface S_TP2 of the second tip portions, and the lower surface B_TP2 of the second tip portions. Since the protruding pattern PP and the pixel definition layer PDL are further coupled with each other in the lower surface B_TP2 of the second tip portions, the adhesive force between the protruding pattern PP and the pixel definition layer PDL may be improved. In detail, when the adhesive force is improved, the protruding pattern PP may effectively cover the sixth insulating layer 60, and thus, a width of the protruding pattern PP may be reduced.

As the first groove GV1 recessed in the thickness direction is defined in the sixth insulating layer 60 and the first hole H1 corresponding to the first groove GV1 is defined through the pixel definition layer PDL, first portions of the pixel definition layer PDL which correspond to the protruding pattern PP, may be disconnected from second portions of the pixel definition layer PDL which correspond to the first and second light emitting elements ED1 and ED2. That is patterns of the pixel definition layer patterns may be disposed spaced apart from each other in a direction along the sixth insulating layer 60, where holes are respectively defined between the pixel definition layer patterns. Accordingly, even though a foreign matter is generated when the fine metal mask (FMM) collides with the protruding pattern PP during the evaporation process using the fine metal mask (FMM) in a method of providing the display device DD, the foreign matter generated near the protruding pattern PP may not travel from the protruding pattern PP and to the first and second light emitting elements ED1 and ED2.

As the adhesive force between the pixel definition layer PDL and the first inorganic layer 141 is improved and the protruding pattern PP has an isolated shape (e.g., an island shape or a discrete shape in the plan view) spaced apart from the first and second light emitting elements ED1 and ED2 by the first groove GV1 and the first hole H1, a moisture penetration phenomenon caused by outgassing gases which infiltrate into an area where the first inorganic layer 141 thinly covers the foreign matter (or a lower end of the foreign matter) formed on the sixth insulating layer 60 may be reduced or prevented.

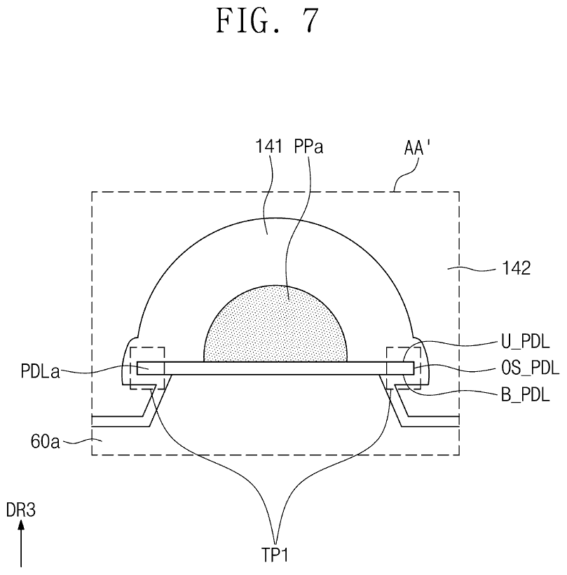

FIG. 7 is an enlarged view of an area AA′ of FIG. 5. In FIG. 7, the same reference numerals denote the same elements in FIGS. 1 to 6, and thus, detailed descriptions of the same elements will be omitted.

Referring to FIG. 7, a protruding pattern PPa may be spaced apart from a sixth insulating layer 60a in the third direction DR3. As an example, the protruding pattern PPa may be spaced apart from the sixth insulating layer 60a owing to a pixel definition layer PDLa interposed therebetween when viewed in the cross-section (e.g., along thickness direction of the pixel definition layer PDLa). An entirety of a lower surface of the protruding pattern PPa may be in contact with an upper surface U_PDL of the pixel definition layer PDLa. That is, the protruding pattern PPa may be disposed only on the pixel definition layer PDLa without being disposed extended into a thickness of the sixth insulating layer 60a. As being in contact, elements may form an interface (e.g., a physical interface) therebetween.

Different from the sixth insulating layer 60 of FIGS. 5 and 6, a second groove GV2 (refer to FIGS. 5 and 6) may not be defined in the sixth insulating layer 60a of FIG. 7. That is, the protruding pattern PPa of FIG. 7 may not be formed extended into a thickness of the sixth insulating layer 60a, and a volume of the protruding pattern PPa may be reduced. Therefore, an amount of protruding pattern material used to form the protruding pattern PPa may be reduced.

A lower surface B_PDL of the pixel definition layer PDLa may be directly in contact with the sixth insulating layer 60a. The pixel definition layer PDLa may include the upper surface U_PDL, a side surface OS_PDL, and the lower surface B_PDL.

According to the present embodiment, as the lower surface B_PDL of the pixel definition layer PDLa at a first tip portion TP1 is directly coupled with a first inorganic layer 141, an adhesive force between the pixel definition layer PDLa and the first inorganic layer 141 may be improved. As an example, since the pixel definition layer PDLa includes the first tip portion TP1, the first inorganic layer 141 may be coupled not only with the side surface OS_PDL and the upper surface U_PDL of the pixel definition layer PDLa but also with a portion of the lower surface B_PDL which is located at the first tip portion TP1 of the pixel definition layer PDLa. Accordingly, the pixel definition layer PDLa and the first inorganic layer 141 are further coupled with each other at the lower surface B_PDL of the first tip portion TP1 of the pixel definition layer PDLa, the adhesive force between the pixel definition layer PDLa and the first inorganic layer 141 may be improved.

In addition, as the pixel definition layer PDLa including an inorganic material is directly coupled with the first inorganic layer 141 including an inorganic material, the adhesive force between the pixel definition layer PDLa and the first inorganic layer 141 may be improved. Therefore, defects in the pixels PX, which are caused by a foreign substance which enters the encapsulation layer (refer to the thin film encapsulation layer 140 of FIG. 5), may be reduced or prevented, and an encapsulating ability of the thin film encapsulation layer 140 may be improved.

The first inorganic layer 141 may be disposed on the sixth insulating layer 60a and the pixel definition layer PDLa and may cover the protruding pattern PPa. As an example, the first inorganic layer 141 may cover the lower surface B_PDL, the side surface OS_PDL, and the upper surface U_PDL of the pixel definition layer PDL and may cover an upper surface of the protruding pattern PPa. The first inorganic layer 141 may completely cover the lower surface B_PDL, the side surface OS_PDL, and the upper surface U_PDL of the pixel definition layer PDL, together with completely covering the upper surface of the protruding pattern PPa.

FIG. 8 is a cross-sectional view of a display device DD according to an embodiment of the present disclosure. In FIG. 8, the same/similar reference numerals denote the same/similar elements in FIGS. 1 to 6, and thus, detailed descriptions of the same/similar elements will be omitted.

Referring to FIG. 8, a third groove GV3 may be further defined in a sixth insulating layer 60b. The third groove GV3 may have a closed-curve shape surrounding a protruding pattern PP when viewed in the plane. As an example, a first groove GV1 may surround the protruding pattern PP, and the third groove GV3 may surround the first groove GV1 when viewed in the plane. That is, the first groove GV1 may be defined adjacent to the protruding pattern PP, and the third groove GV3 may be defined adjacent to first and second light emitting elements ED1 and ED2, such as to be further from the protruding pattern PP than the first groove GV1. In FIG. 8, each of the first and third grooves GV1 and GV3 may be provided in plural within the sixth insulating layer 60b. A pair of grooves GV1 and GV3 may correspond to a same protruding pattern.

According to the present disclosure, since the first groove GV1 and the third groove GV3 are recessed in the thickness direction, first portions of a pixel definition layer PDL, which correspond to the protruding pattern PP, may be disconnected from second portions of the pixel definition layer PDL, which correspond to the first and second light emitting elements ED1 and ED2. In addition, as the third groove GV3 is further defined in the sixth insulating layer 60b, a separation distance between the protruding pattern PP and the first and second light emitting elements ED1 and ED2 may increase.

The pixel definition layer PDL may include first tip portions TP1, and an adhesive force between the pixel definition layer PDL and the first inorganic layer 141 may be improved by direct bonding between components containing inorganic materials at the first tips. In addition, the protruding pattern PP may have an isolated shape spaced apart from the first and second light emitting elements ED1 and ED2 due to the first groove GV1, the third groove GV3 corresponding to a same first hole (e.g., a same one of first hole H1). Accordingly, a foreign matter generated adjacent to the protruding pattern PP may be effectively prevented from moving to the first and second light emitting elements ED1 and ED2, and a moisture penetration phenomenon caused by outgassing gases which infiltrate into an area where the first inorganic layer 141 thinly covers the foreign matter (or a lower end of the foreign matter) may be reduced or prevented.

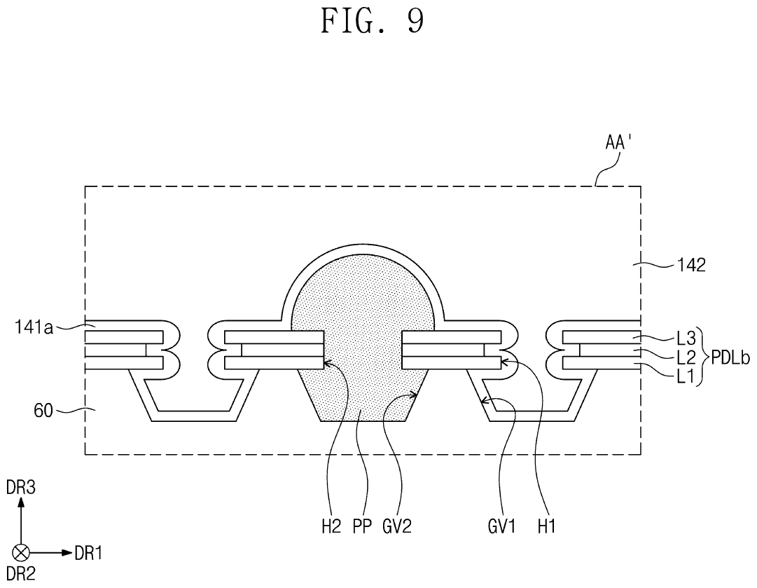

FIG. 9 is an enlarged view of an area AA′ of FIG. 5. In FIG. 9, the same/similar reference numerals denote the same/similar elements in FIGS. 1 to 6, and thus, detailed descriptions of the same/similar elements will be omitted.

Referring to FIG. 9, a pixel definition layer PDLb may be disposed on a sixth insulating layer 60. The pixel definition layer PDLb may include a first layer L1 as a first sub-layer, a second layer L2 as a second sub-layer, and a third layer L3 as a third sub-layer. The first layer L1 may be disposed on the sixth insulating layer 60, the second layer L2 may be disposed on the first layer L1, and the third layer L3 may be disposed on the second layer L2. The first layer L1 and the third layer L3 may include an inorganic material, and the second layer L2 may include an organic material.

At a respective hole in the pixel definition layer PDLb, a second end of the second layer L2 may be recessed in a direction away from a center of a first groove GV1 as compared to a first end of the first layer L1 and third end of the third layer L3. As an example, the second layer L2 may be recessed in a direction parallel to the first direction DR1 and in a direction away from the center of the first groove GV1 as compared to the first layer L1 and the third layer L3. The first layer L1 and the third layer L3 may protrude toward the center of the first groove GV1 further than the second end of the second layer L2. The first layer L1 and the third layer L3 may have a shape of tip portion (e.g., a first sub-tip and a second sub-tip) with respect to the second end of the second layer L2. Thus, the first layer L1 and the third layer L3 may include a plurality of tip portions (e.g., sub-tips) arranged in the thickness direction of the pixel definition layer PDLb.

FIG. 9 shows the pixel definition layer PDLb including the first layer L1, the second layer L2, and the third layer L3 as a representative example, however, the number of layers constituting the pixel definition layer PDLb should not be limited thereto or thereby. The stack structure including the first layer L1, the second layer L2, and the third layer L3 is merely an example, and a stack structure including two or more sub-layers may be provided.

A first inorganic layer 141a may cover a protruding pattern PP, the pixel definition layer PDLb, and the sixth insulating layer 60. In detail, the first inorganic layer 141a may cover an upper surface, a side surface, and a lower surface of the pixel definition layer PDLb and may cover a side surface and a lower surface of the sixth insulating layer 60 which define the first groove GV1, and an upper surface of the protruding pattern PP. The first inorganic layer 141a may cover the side surface of the pixel definition layer PDLb along shapes or profiles of the sub-surfaces of the first, second, and third layers L1, L2, and L3. As an example, a recessed portion of the first inorganic layer 141a which is in contact with the second layer L2 may be partially recessed to cover the pixel definition layer PDLb at each of the first, second and third ends.

In an embodiment, within the first tip portion TP1, the pixel definition layer PDL includes a first layer L1, a second layer L2 and a third layer L3 in order from the insulating layer (e.g., the sixth insulating layer 60). At the first hole H1, a side surface of the second layer L2 is recessed from a side surface of the first layer L1 and a side surface of the third layer L3. The layer which is on the light emitting element ED (e.g., the first inorganic layer 141a) contacts an upper surface, the side surface and a lower surface of each of the first layer L1 and the third layer L3, and the side surface of the second layer L2.

As the pixel definition layer PDLb includes the first, second, and third layers L1, L2, and L3, the plural tip portions (e.g., sub-tips) may be formed. The first inorganic layer 141a may cover not only a side surface and an upper surface of the first, second, and third layers L1, L2, and L3 of the pixel definition layer PDLb but also a lower surface thereof. Accordingly, the first inorganic layer 141a may be further coupled with the lower surface of the first layer L1 and the third layer L3 of the pixel definition layer PDLb, and thus, the adhesive force between the pixel definition layer PDLb and the first inorganic layer 141a may be more effectively improved.

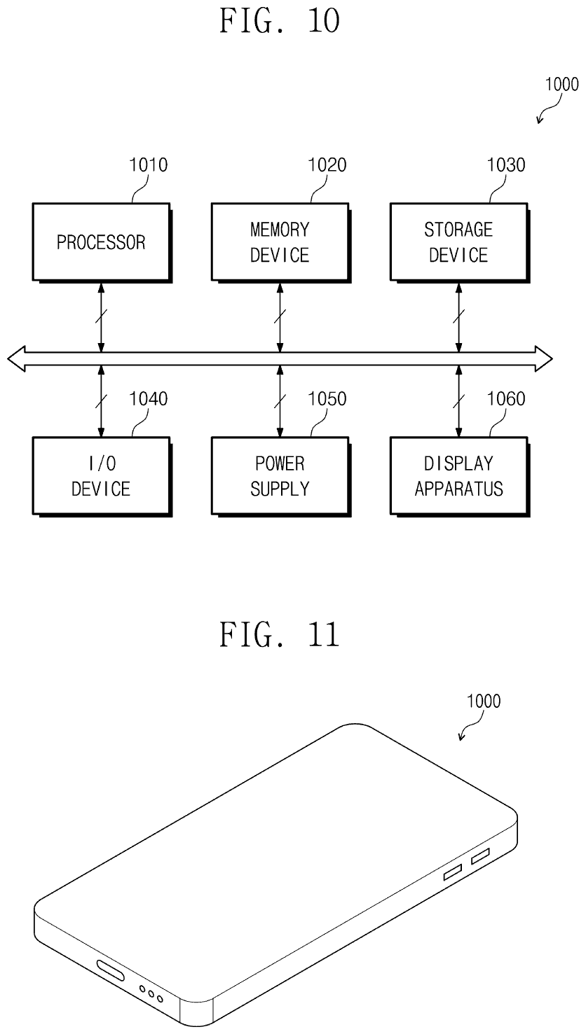

FIG. 10 is a block diagram illustrating an electronic device according to an embodiment. FIG. 111 is a view illustrating an example of the electronic device of FIG. 10 implemented as a smartphone.

Referring to FIGS. 10 and 11, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a home appliance, a tablet PC, a vehicle display, a computer monitor, a notebook computer, an entertainment device like a head-mounted display device, etc. In addition, the electronic device 1000 may be a television, a monitor, a notebook computer, or a tablet. In addition, the electronic device 1000 may be a car.

The display device DD according to the embodiments may be applied to a device included in a computer, a notebook, a mobile phone, a smartphone, a smart pad, a PMP, a PDA, an MP3 player, or the like.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present invention shall be determined according to the attached claims.

What is claimed is:

1. A display device comprising:
a base layer;
an insulating layer which is on the base layer and defines a first groove therein;
a light emitting element on the insulating layer comprising a first electrode, a light emitting pattern and a second electrode;
a pixel definition layer which is on the insulating layer and defines each of a light emitting opening which exposes the first electrode to outside the pixel definition layer and a first hole which is adjacent to the light emitting opening and overlaps the first groove; and
a protruding pattern which is on the insulating layer and directly contacts the pixel definition layer, the protruding pattern spaced apart from the light emitting element with the first hole and the first groove therebetween.

2. The display device of claim 1, wherein the first groove has a closed-curve shape extended around the protruding pattern.

3. The display device of claim 1, wherein
a side surface of the insulating layer defines the first groove, and
the pixel definition layer comprises a first tip portion at the first groove which protrudes further than the side surface of the insulating layer and defines the first hole.

4. The display device of claim 1, further comprising a first inorganic layer covering the light emitting element and the protruding pattern.

5. The display device of claim 4, wherein
the first groove is defined by a side surface and a lower surface of the insulating layer, and
the first inorganic layer covers the side surface and the lower surface of the insulating layer which define the first groove.

6. The display device of claim 4, wherein
the first hole is defined by a side surface of the pixel definition layer,
a lower surface of the pixel definition layer extends from the side surface of the pixel definition layer and faces the insulating layer, and
the first inorganic layer contacts the side surface of the pixel definition layer which defines the first hole and contacts the lower surface of the pixel definition layer.

7. The display device of claim 4, further comprising an organic layer on the first inorganic layer,
wherein a portion of the organic layer is inside the first hole of the pixel definition layer.

8. The display device of claim 1, wherein
the insulating layer further defines a second groove therein which overlaps the protruding pattern, and
the pixel definition layer further defines a second hole therein overlapping the second groove.

9. The display device of claim 8, wherein
a side surface of the insulating layer defines the second groove, and
the pixel definition layer comprises a second tip portion at the second groove which protrudes further than the side surface of the insulating layer and defines the second hole.

10. The display device of claim 9, wherein the protruding pattern contacts an upper surface, a side surface, and a lower surface of the second tip portion of the pixel definition layer.

11. The display device of claim 1, wherein the protruding pattern is spaced apart from the insulating layer by the pixel definition layer therebetween along a thickness direction of the pixel definition layer.

12. The display device of claim 11, wherein an entirety of a lower surface of the protruding pattern is in contact with an upper surface of the pixel definition layer.

13. The display device of claim 1, wherein the insulating layer further defines a third groove therein which surrounds the first groove.

14. The display device of claim 1, wherein
the pixel definition layer comprises a first layer, a second layer and a third layer in order from the insulating layer, and
at the first hole, an end of the second layer is recessed from an end of the first layer and an end of the third layer.

15. The display device of claim 14, wherein within the pixel definition layer:
the first layer and the third layer comprise an inorganic material, and
the second layer comprises an organic material.

16. The display device of claim 1, further comprising:
the light emitting element provided in plural including a first light emitting element and a second light emitting element which is spaced apart from the first light emitting element;
the protruding pattern between the first light emitting element and the second light emitting element; and
the first groove of the insulating layer between the protruding pattern and each of the first light emitting element and the second light emitting element.

17. An electronic device comprising:
a display panel which generates an image; and
the display panel comprising:
a base layer;
an insulating layer which is on the base layer and defines a first groove therein;
a light emitting element on the insulating layer;
a pixel definition layer which is on the insulating layer and defines each of:
a light emitting opening corresponding to the light emitting element,
a first hole which is adjacent to the light emitting opening and overlaps the first groove, and
a first tip portion which overlaps the first groove; and
a layer which is on the light emitting element and contacts an upper surface, a side surface and a lower surface of the first tip portion.

18. The electronic device of claim 17, wherein the layer which is on the light emitting element comprises an inorganic encapsulation layer.

19. The electronic device of claim 17, further comprising:
the insulating layer further defining a second groove therein which is spaced apart from the first groove,
the pixel definition layer further defining:
a second hole therein overlapping the second groove and spaced apart from the light emitting element, and
a second tip portion which overlaps the second groove, and
a protruding pattern which is on the insulating layer, spaced apart from the light emitting element by the first groove, and contacts an upper surface, a side surface and a lower surface of the second tip portion.

20. The electronic device of claim 17, wherein
within the first tip portion, the pixel definition layer comprises a first layer, a second layer and a third layer in order from the insulating layer,
at the first hole, a side surface of the second layer is recessed from a side surface of the first layer and a side surface of the third layer, and
the layer which is on the light emitting element contacts:
an upper surface, the side surface and a lower surface of each of the first layer and the third layer, and
the side surface of the second layer.
